(19) United States
(12) Patent Application Publication
(10) Pub. No.: US 2012/0074443 A1
(43) Pub. Date: Mar. 29, 2012

(54) LED package structure

(75) Inventors: Wen-Hsiung Li, Taichung City (TW); I Chih Huang, Shulin City (TW); Hui-Wen Xu, Danshui Township (TW)

(73) Assignee: Forward Electronics Co., Ltd., Taipei City (TW)

(21) Appl. No.: 12/929,142

(22) Filed: Jan. 4, 2011

(30) Foreign Application Priority Data
Sep. 29, 2010 (TW) 099218793

(51) Int. Cl. H01L 33/00

(52) U.S. Cl. 257/98; 257/E33.055

(57) ABSTRACT

An LED package structure includes a base, an LED chip, a frame, and a microstructure lens. The LED chip is arranged on the base. The microstructure lens is arranged on the LED chip, and is a first-order optical lens being subject to surface optical microstructure treatment. The frame is provided for securing the microstructure lens on the base. The microstructure lens of the LED package structure can concentrate the light emitted from the LED chip or vary light patterns of the light emitted from the LED chip so as to achieve the purpose of increasing brightness and luminous angles.

### BACKGROUND OF THE INVENTION

1. Field of the Invention

The present invention relates to an LED (Light-Emitting Diode) package structure, and more particularly, to an LED package structure having a microstructure lens being subject to surface optical microstructure treatment.

2. Description of Related Art

Generally speaking, LEDs, as compared with conventional light sources, have advantages of long life, small size, low failure rate, low power consumption, rapid reaction and etc. Therefore, LEDs have been widely applied to various electronic products, equipments, and household electric appliances. However, due to low light intensity, LEDs are, at present, mostly employed for message indication.

Please refer to FIG. 1, a schematic diagram illustrating a conventional LED package structure, the conventional LED package structure 1 comprises an LED chip 11, a transparent lens 12, a fluorescent colloidal layer 13, and a base 14. Wherein, the LED chip 11 is arranged on the base 14. The fluorescent colloidal layer 13 is formed on the LED chip 11 by silicon gluing or injection molding. The transparent lens 12 is arranged outside of the fluorescent colloidal layer 13 for controlling luminous angles and luminous efficiency of the LED package structure 1. Nevertheless, as limited by lens curvature, the light emitted from the LED chip 11 relates mostly to a total internal reflection in the transparent lens 12. As a result, there is a difficulty to raise the luminous efficiency of the conventional LED package structure 1. In addition, in order to reach to an optimum luminous efficiency, the luminous angle of the conventional LED package structure 1 is limited to 100-120 degrees, and any further increase for the luminous angle is impossible.

Given the above, an innovative LED package structure, for which brightness and luminous angle haven been effectively increased, has been eventually accomplished after research and repeated experiments.

### SUMMARY OF THE INVENTION

A primary object of the present invention is to provide an LED package structure, characterized in that light emitted from the LED is adjusted by a microstructure lens being subject to surface optical microstructure treatment so as to achieve the purpose of increasing brightness and luminous angles.

According to one aspect of the present invention, the LED package structure comprises a base, an LED chip, and a microstructure lens. The LED chip is arranged on the base. The microstructure lens installed on the LED chip is a first-order optical lens subject to surface optical microstructure treatment.

Wherein, the microstructure lens forms an equivalent continuous optical surface through the surface optical microstructure. When the light emitted from the LED chip passes through the microstructure lens, which has been subject to surface optical microstructure treatment, distribution of the light will be varied due to reflection, refraction, and diffusion of the light. For example, the LED package structure of the present invention could concentrate the diffuse light through the microstructure lens, to reduce light consumption rate, so as to increase brightness of the LED package structure.

The above-mentioned LED chip may be a DC LED chip, or an AC LED chip.

The LED package structure of the present invention may further comprise a fluorescent colloidal layer formed on the LED chip, and the microstructure lens is disposed on the fluorescent colloidal layer.

The LED package structure of the present invention may further comprise a frame disposed on the microstructure lens for securing the microstructure lens on the base.

The LED package structure of the present invention may further comprise a transparent housing formed on the microstructure lens for preventing the microstructure lens from being damaged.

Other objects, advantages, and novel features of the present invention will become more apparent from the following detailed description when taken in conjunction with the accompanying drawings.

### BRIEF DESCRIPTION OF THE DRAWINGS

FIG. 1 is a schematic diagram illustrating a conventional LED package structure;

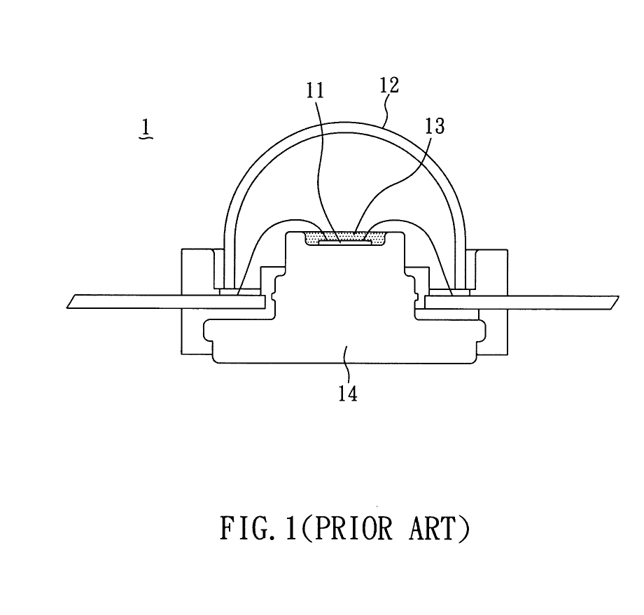

FIG. 2A is a perspective view illustrating an LED package structure according to a first embodiment of the present invention;

FIG. 2B is an exploded view illustrating the LED package structure according to the first embodiment of the present invention;

FIG. 3 is a light pattern diagram for the LED package structure according to the first embodiment of the present invention;

FIG. 4A is a perspective view illustrating an LED package structure according to a second embodiment of the present invention; and

FIG. 4B is an exploded view illustrating the LED package structure according to the second embodiment of the present invention.

### DETAILED DESCRIPTION OF THE PREFERRED EMBODIMENTS

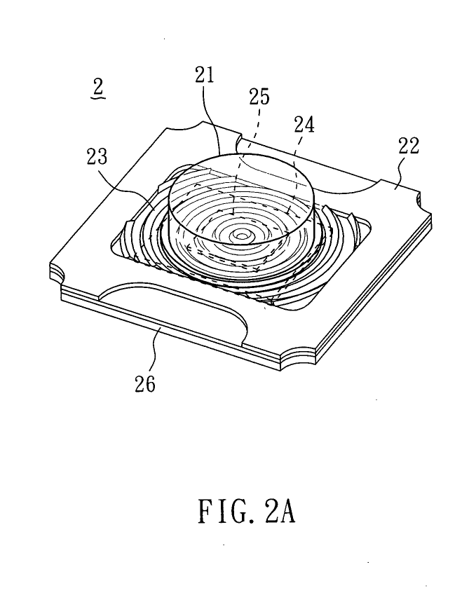

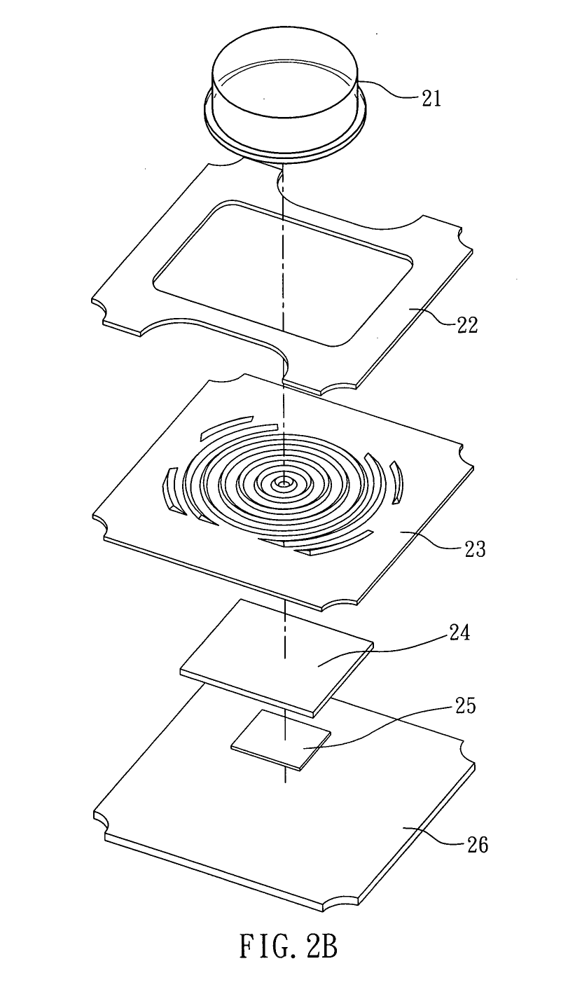

Referring to FIGS. 2A and 2B, perspective and exploded views illustrating an LED package structure according to a first embodiment of the present invention, the LED package structure 2 comprises a transparent housing 21, a frame 22, a microstructure lens 23, a fluorescent colloidal layer 24, an LED chip 25, and a base 26. Wherein, the microstructure lens 23 is a first-order optical lens being subject to surface optical microstructure treatment. The LED chip 25 may be a DC LED chip or an AC LED chip.

The LED chip 25 is arranged on the base 26, the fluorescent colloidal layer 24 is formed on the LED chip 25 by silicon gluing or injection molding, the microstructure lens 23 is arranged on the fluorescent colloidal layer 24, and the frame 22 is arranged on the microstructure lens 23 for securing the microstructure lens 23 on the base 26. The transparent housing 21 is arranged on the microstructure lens 23 for preventing the surface of the microstructure lens 23 from being damaged. The thickness of the microstructure lens 23 is preferably 0.25 to 0.30 mm. The transparent housing 21 is preferably a cylindrical housing, which has a thickness of 1.0 to 2.0 mm and a bottom with a radius of 3.5 to 4.5 mm preferably.

According to the present invention, the microstructure lens 23 has a surface optical microstructure formed with multiple concentric annular protrusions, so that the light emitted from the LED chip 25 can be concentrated, and in the meantime, light consumption rate can be reduced. Therefore, the brightness of the LED package structure 2 can be increased effectively through the microstructure lens 23.

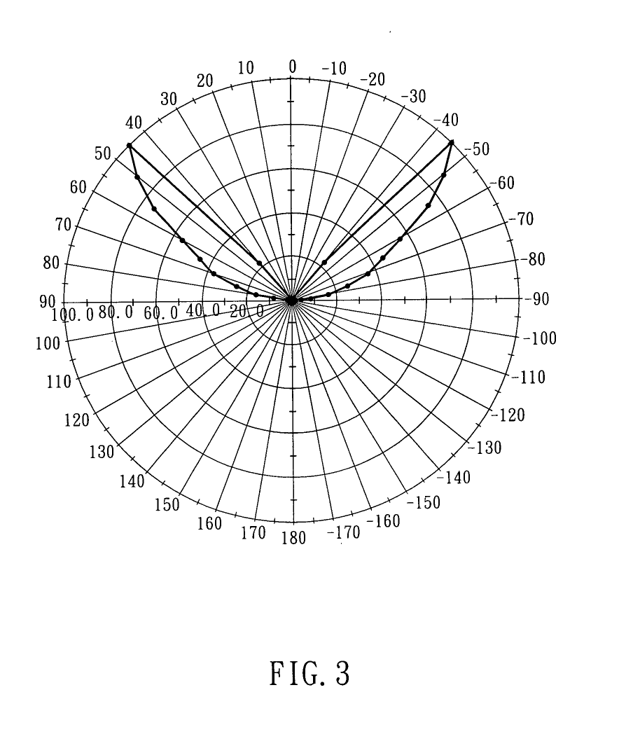

Please refer to FIG. 3, a light pattern diagram for the LED package structure according to the first embodiment of the present invention, which is obtained by simulation. In the present embodiment, the thickness of the microstructure lens 23 is 0.27 mm, the transparent housing 21 is a cylindrical housing with a thickness of 1.5 mm and a radius of 4.1 mm at the bottom thereof, and the LED chip 25 is an AC blue-light LED chip. As shown in FIG. 3, the LED package structure 2 not only has concentrated luminous angles, but also has a greater brightness. Moreover, as compared with the conventional LED package structure 1 which employs an AC blue-light LED chip acting as the LED chip 11, the luminous efficiency of the LED package structure 2 of the present embodiment is increasing 20 to 40%.

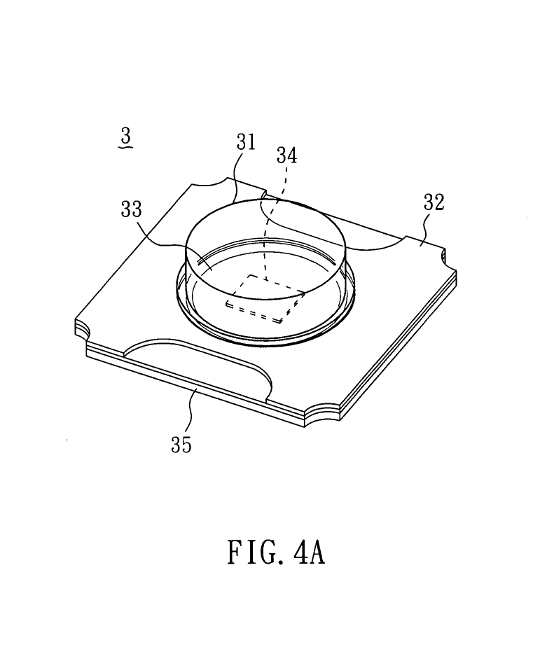

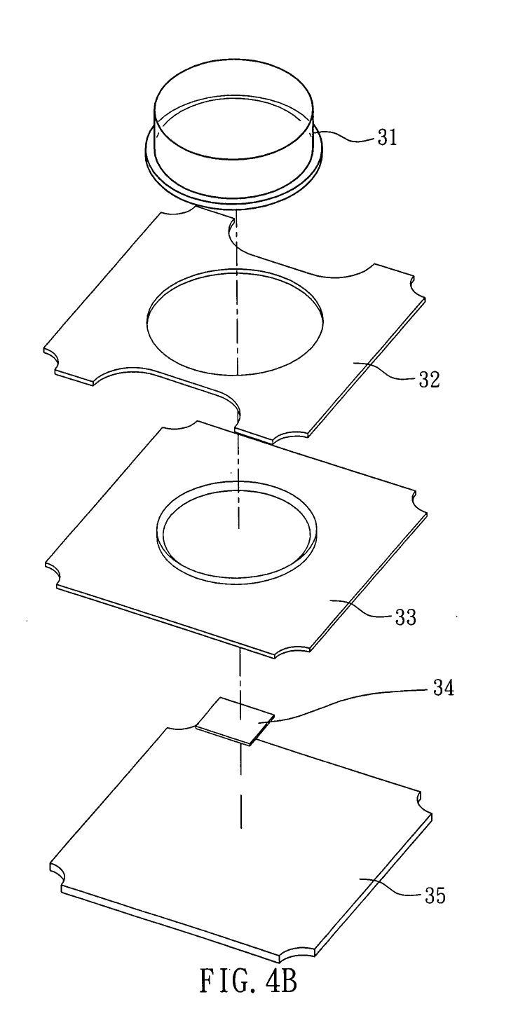

Please refer to FIGS. 4A and 4B, perspective and exploded views illustrating an LED package structure 3 according to a second embodiment of the present invention, the LED package structure 3 comprises a transparent housing 31, a frame 32, a microstructure lens 33, an LED chip 34, and a base 35. The LED chip 34 is arranged on the base 35, and that the microstructure lens 33 is arranged on the LED chip 34. The frame 32 is arranged on the microstructure lens 33 for securing the microstructure lens 33 on the base 35. The transparent housing 31 is arranged on the microstructure lens 33.

In the present embodiment, the surface optical microstructure of the microstructure lens 33 of the LED package structure 3 is an annular protrusion with heights increasing gradually from inside toward outside. Light patterns of the light emitted from the LED chip 34 can be varied through the surface optical microstructure, to thereby increase the luminous angle of the LED package structure.

In view of the above, through the surface optical microstructure of the microstructure lens, the LED package structure of the present invention varies distribution or light patterns of the light emitted from the LED chip. For example, the light, which was originally diffused, can be concentrated to reduce light consumption rate, to thereby achieve the purpose of increasing the brightness or luminous angles of the LED package structure.

Further, according to the present invention, only a significantly thin microstructure lens is employed for adjusting the luminous angles and brightness of the LED package structure. Since the total thickness of the LED package structure is 1 to 3 mm, the present invention effectively decreases the dimensions required for the LED package structure compared with the dimensions of the conventional LED package structures.

Although the present invention has been explained in relation to its preferred embodiments, it is to be understood that many other possible modifications and variations can be made without departing from the scope of the invention as hereinafter claimed.

What is claimed is:

1. An LED package structure, comprising:
a base;
an LED chip, arranged on the base; and
a microstructure lens, arranged on the LED chip, which is a first-order optical lens being subject to surface optical microstructure treatment.

2. The LED package structure as claimed in claim 1, wherein the surface optical microstructure of the microstructure lens is formed with multiple concentric annular protrusions.

3. The LED package structure as claimed in claim 1, wherein the surface optical microstructure is an annular protrusion with heights increasing gradually from inside toward outside.

4. The LED package structure as claimed in claim 1, further comprising a fluorescent colloidal layer formed on the LED chip, and the microstructure lens is disposed on the fluorescent colloidal layer.

5. The LED package structure as claimed in claim 1, further comprising a frame disposed on the microstructure lens for securing the microstructure lens on the base.

6. The LED package structure as claimed in claim 1, further comprising a transparent housing arranged on the microstructure lens for preventing the microstructure lens from being damaged.

7. The LED package structure as claimed in claim 1, wherein the LED chip is a DC LED chip.

8. The LED package structure as claimed in claim 1, wherein the LED chip is an AC LED chip.

9. The LED package structure as claimed in claim 6, wherein the thickness of the microstructure lens is 0.25 to 0.30 mm, and the thickness of the transparent housing is 1.0 to 2.0 mm.
